(19) United States
(12) Patent Application Publication
(10) Pub. No.: US 2005/0183884 A1
(43) Pub. Date: Aug. 25, 2005

(54) Flexible printed circuit board

(75) Inventor: Pi-Chuan Su, Kaohsiung (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Arima Display Corporation, Kaohsiung (TW)

(21) Appl. No.: 10/786,745

(22) Filed: Feb. 25, 2004

(51) Int. Cl. H05K 1/03; H05K 1/09

(52) U.S. Cl. 174/257; 174/258; 349/150

(57) ABSTRACT

A flexible printed circuit with a broadened anisotropic conductive film is provided. The flexible printed circuit includes a substrate layer and a circuit layer, characterized in that a pitch of the anisotropic conductive film is broadened to be ranged from 0.5 mm to 3.0 mm. It has even and low impedance, even breakage of conductive particles, even pressure, and thus has good reliability of the anisotropic conductive film for use in handheld electronic devices.

### FIELD OF THE INVENTION

The present invention relates to a flexible printed circuit board, particularly to a flexible printed circuit board with an anisotropic conductive film, which has even and low impedance, even breakage of conductive particles, even pressure, and thus has good reliability of the anisotropic conductive film for use in handheld electrical devices.

### BACKGROUND OF THE INVENTION

Please refer to FIG. 1A and FIG. 1B. They are schematic views showing the liquid crystal display devices provided in the industry with the prevalence of handheld electrical devices, such as cellular phone, PDA, smart phone, stock manager, etc. In the drawings, the flexible printed circuit boards 61, 71 can be built with a copper circuit print and can be fixed with integrated circuits 615, 715 respectively. The surface mounting devices (SMD) 716 (such as surface mounting capacitor, surface mounting resistor, LED and etc.) can be mounted on the flexible printed circuit board 71 as well. The flexible printed circuit boards 61, 71 are electrically connected to the upper liquid crystal displays (LCD) 62, 72 via the anisotropic conductive films 612, 712 with the pitch under 0.1 mm respectively.

Please refer to FIGS. 2A and 2B. FIG. 2A is a side view showing the main portion of the flexible printed circuit board according to the prior art, and FIG. 2B is a diagram illustrating the structure of the conventional liquid crystal display of the handheld electrical device according to the prior art. In FIG. 2A, the main portion 811 of the flexible printed circuit board 81 includes the plastic layer 812, the first copper layer 813, and the second copper layer 814. The plastic layer 812 not only can be built with the first copper layer 813 and the second copper layer 814 of the copper circuit print, but also can be fixed with an integrated circuit and surface mounting devices, such as surface mounting capacitor, surface mounting resistor, LED, and etc. The main portion 811 of the flexible printed circuit board 81 is electrically connected to the upper LCD 82 via the anisotropic conductive film 8121 with the pitch under 0.1 mm.

In FIG. 2B, the anisotropic conductive film 8121 correspondingly bonds to the indium-tin oxide layer 821 of the LCD 82 for transferring a liquid crystal control signal to the LCD panel via the indium-tin oxide layer 821. The bottom end of the flexible printed circuit board 81 is the golden-finger region 817. Under the golden-finger region 817, it is the LCD circuit board 83 made up of the main portion 831 and the connector portion 832. The connector portion 832 is also called welding portion and designed to be connected with the golden-finger region 817.

The anisotropic conductive film 8121 contains plural conductive particles. The conductive particles must be broken in order to conduct electricity, if not, they cannot conduct electricity. However, the conductive particles are often broken unevenly. Though the conductive particles of uneven breakage can still conduct electricity, they could reduce the reliability of the anisotropic conductive film 8121. In the conventional technique, the pitch of the anisotropic conductive film 8121 is about 0.1 mm, as shown in the A and B portions of FIG. 2B. As the pitch of the anisotropic conductive film 8121 is kept under 0.1 mm, it is easier to reach the requirement of smooth for the anisotropic conductive film 8121. However, in order to reduce the impedance and adapt to the standards of the integrated circuit industry, the pitch of the anisotropic conductive film 8121 is broadened and wider than 0.5 mm. As a result, the anisotropic conductive film 8121 is not smooth, which causes the uneven breakage of the conductive particles.

In order to overcome the drawbacks in the prior art, a flexible printed circuit board is provided. In the particular design, the anisotropic conductive film with broadened pitch has the features of even and low impedance, even breakage of conductive particles, even pressure, and thus the anisotropic conductive film for use in handheld electrical devices will have good reliability.

### SUMMARY OF THE INVENTION

It is an object of the present invention to provide a flexible printed circuit board with an anisotropic conductive film for use in handheld electrical devices.

It is another object of the present invention to provide a flexible printed circuit board with an anisotropic conductive film, which has the features of even and low impedance, even breakage of conductive particles, even pressure, and thus a good reliability of the anisotropic conductive film for use in handheld electrical devices is achieved.

In accordance with an aspect of the present invention, a flexible printed circuit board includes a substrate layer; at least a circuit layer formed on the substrate layer; and a conductive film layer formed on one end of the circuit layer, characterized in that a pitch of the conductive film layer is broadened to be ranged from 0.5 mm to 3.0 mm.

Preferably, the other end of the circuit layer is formed to be a golden-finger region and is electrically connected to the LCD circuit board.

Preferably, the anisotropic conductive film includes conductive particles and sticky polymers.

Preferably, the conductive particles are one of metal-plated polymer particles and nickel particles.

Preferably, the metal of the metal-plated polymer particles is selected from a group consisting of a nickel, a copper, a gold, and a silver.

Preferably, the substrate layer is a plastic layer.

Preferably, the plastic layer includes a polyimide layer and a polypropylene/epoxy resin layer.

Preferably, the plastic layer includes a polyimide layer.

Preferably, the circuit layer is a copper circuit layer.

Preferably, the circuit layer further includes an integrated circuit disposed thereon which is packaged by using one of a tape carrier package and a chip on film.

Preferably, the circuit layer further includes surface mounting devices.

Preferably, the conductive film is an anisotropic conductive film.

Preferably, the flexible circuit board is connected to a liquid crystal display via the conductive film layer.

In accordance with another aspect of the present invention, a flexible printed circuit board includes at least two substrate layers; at least a circuit layer formed between every adjacent two substrate layers; and at least a conductive film layer formed on one end of the circuit layer, characterized in that a pitch of the conductive film layer is broadened to be ranged from 0.5 mm to 3.0 mm.

Preferably, the other end of the circuit layer is formed to be a golden-finger region and is electrically connected to the LCD circuit board.

Preferably, the anisotropic conductive film includes conductive particles and sticky polymers.

Preferably, the conductive particles are one of metal-plated polymer particles and nickel particles.

Preferably, the metal of the metal-plated polymer particles is selected from a group consisting of a nickel, a copper, a gold, and a silver.

Preferably, the substrate layer is a plastic layer.

Preferably, the plastic layer includes a polyimide layer and a polypropylene/epoxy resin layer.

Preferably, the plastic layer includes a polyimide layer.

Preferably, the circuit layer is a copper circuit layer.

Preferably, the circuit layer further includes an integrated circuit disposed thereon which is packaged by using one of a tape carrier package and a chip on film.

Preferably, the circuit layer further includes surface mounting devices.

Preferably, the conductive film is an anisotropic conductive film.

Preferably, the flexible circuit board is connected to a liquid crystal display via the conductive film layer.

The foregoing and other features and advantages of the present invention will be more clearly understood through the following descriptions with reference to the drawings, wherein:

### BRIEF DESCRIPTION OF THE DRAWINGS

FIGS. 1A and 1B are schematic views showing the conventional liquid crystal display of the handheld electrical devices according to the prior art;

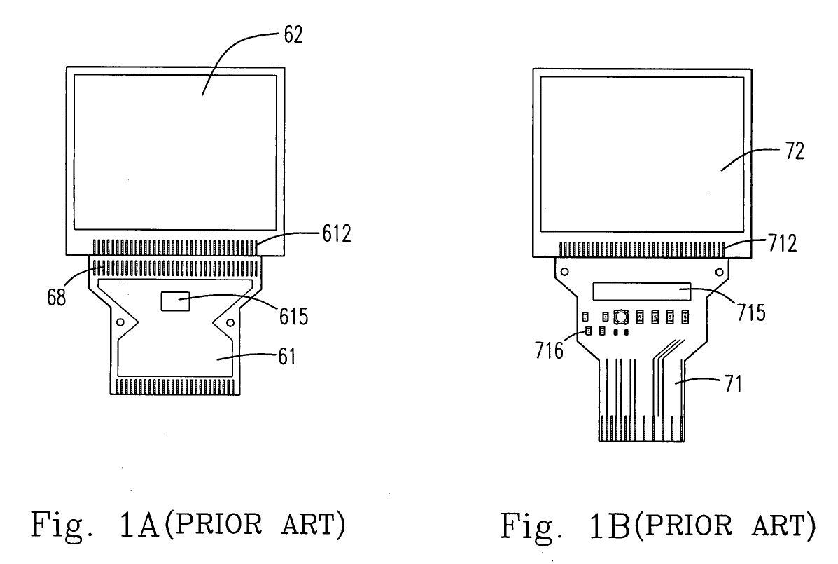

FIG. 2A is a side view showing the main portion of the flexible printed circuit board according to the prior art;

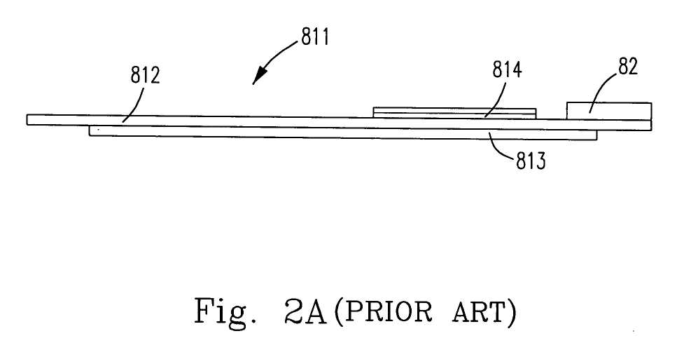

FIG. 2B is a diagram illustrating the structure of the conventional liquid crystal display of the handheld electrical device according to the prior art;

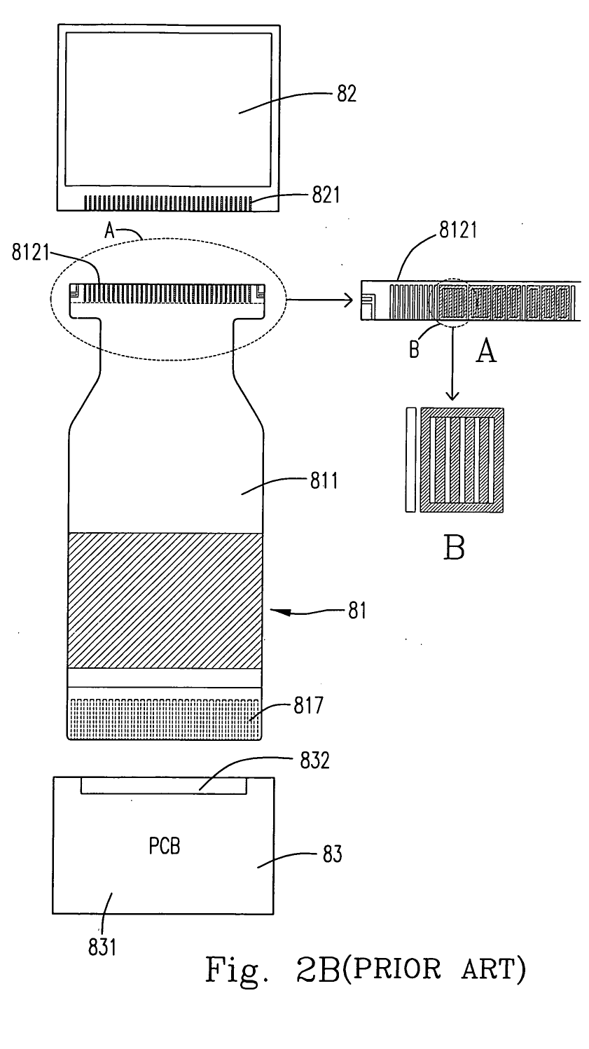

FIG. 3A is a side view showing the main portion of the flexible printed circuit board according to a preferred embodiment of the present invention;

FIG. 3B is a diagram illustrating the structure of the liquid crystal display of the handheld electronic device according to a preferred embodiment of the present invention;

FIG. 4A is a side view showing the main portion of the flexible printed circuit board according to another preferred embodiment of the present invention;

FIG. 4B is a diagram illustrating the structure of the liquid crystal display of handheld electronic device according to another preferred embodiment of the present invention; and

FIG. 5 is a side view of FIG. 3B.

### DETAILED DESCRIPTION OF THE PREFERRED EMBODIMENT

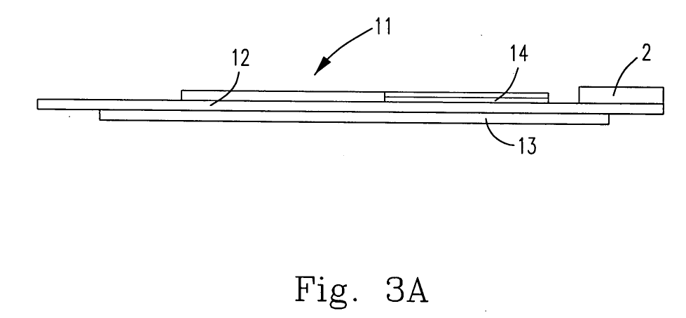

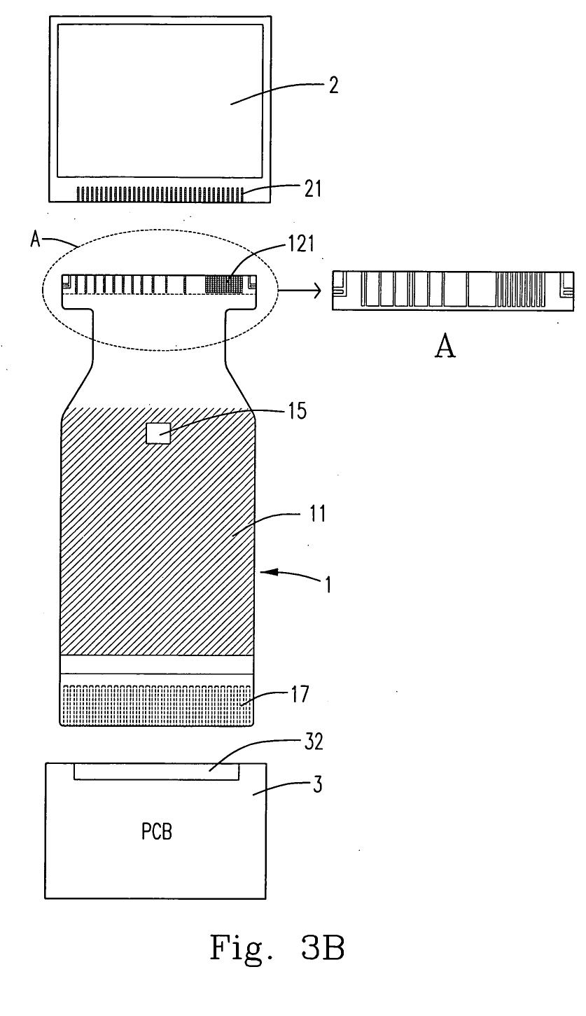

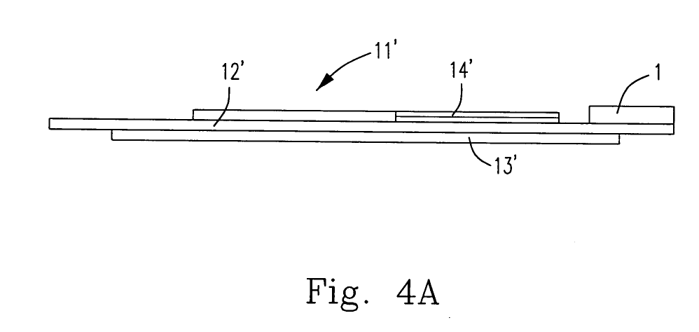

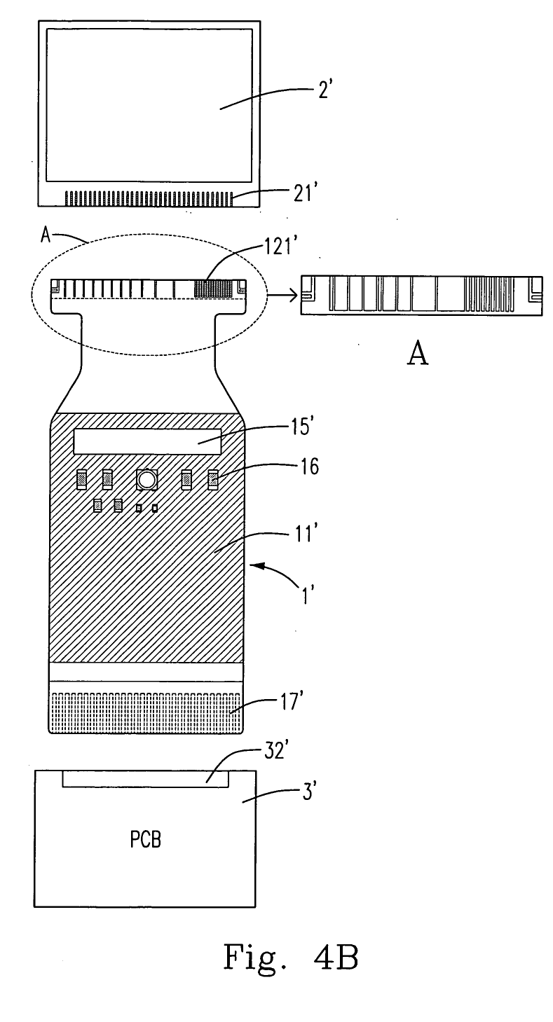

The present invention will now be described more specifically with reference to the following embodiments. In the first embodiment of the present invention, the flexible printed circuit boards 1, 1′ with the broadened anisotropic conductive film respectively have the main portions 11, 11′. Please refer to FIGS. 3A and 4A, which are side views showing the main portions of the flexible printed circuit boards according to the preferred embodiments of the present invention. The main portions 11, 11′ are respectively made up of the first circuit layers (circuit layer) 13, 13′, the second circuit layers (circuit layer) 14, 14′, and the plastic layers (substrate layer) 12,12′. Preferably, the plastic layers 12, 12′ can be polyimide having good flexibility and mechanical property, i.e. all-polyimide flexible printed circuit board. In addition, a polypropylene/epoxy resin layer can be spread on the polyimide layer. Preferably, the first and the second circuit layers 13, 13′, 14, 14′ are printed copper layers regarding the double flexible printed circuits.

Please refer to FIG. 3B which is a diagram illustrating the structure of the liquid crystal display of the handheld electronic device according to the preferred embodiment of the present invention. In FIG. 3B, the upper end of the main body 11 of the flexible printed circuit board 1 of the present invention is electrically connected to the indium-tin oxide layer 21 of the liquid crystal display 2 via the anisotropic conductive film 121. The bottom end of the main body 11 of the flexible printed circuit board 1 of the present invention is electrically connected to the connector 32 (also called welding portion) of the LCD circuit board 3 via the golden-finger region 17. In addition, the flexible printed circuit board 1 can be fixed an integrated circuit 15 by using a tape carrier package.

Please refer to FIG. 4B. The upper end of the main body 11′ of the flexible printed circuit board 1′ of the present invention is electrically connected to the indium-tin oxide layer 21′ of the liquid crystal display 2′ via the anisotropic conductive film 121′. The bottom end of the main body 11′ of the flexible printed circuit board 1′ of the present invention is electrically connected to the connector 32′ (also called welding portion) of the LCD circuit board 3′ via the golden-finger region 17′. In addition, the integrated circuit 15′ and surface mounting devices 16 (such as surface mounting capacitor, surface mounting resistor, LED, and etc.) can be fixed on the flexible printed circuit board 1′ by using a tape carrier package or a chip on film.

In the second embodiment of the present invention, the flexible printed circuit boards 1, 1′ are all-polyimide flexible laminae. For example, it has two layers, three layers, four layers, and six layers.

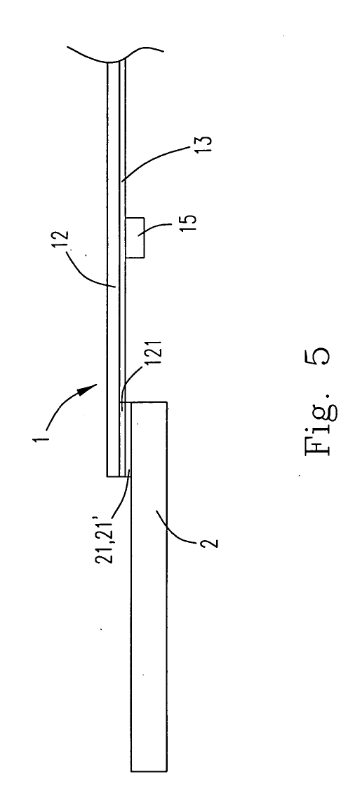

Please refer to FIG. 5 which is a side view of FIG. 3B showing the liquid crystal display of the handheld electronic devices. In the left side, the drawing is the liquid crystal display 2, whose up-right portion is the indium-tin oxide layer 21, 21′. The indium-tin oxide layer 21, 21′ is electrically connected to the anisotropic conductive film 121 located at down-left portion of the flexible printed circuit board 1 by the bonding process. Moreover, the substrate layer 12, the circuit layer 13, and integrated circuit 15 are also shown in the drawing.

In the anisotropic conductive adhesive or anisotropic conductive films 121, 121′ of the present invention, usually the conductive particles are dispersed and mixed in the polymers in a random fashion. The sticky polymers are subsequently transformed into the solid thin films. The conductive particles, typically as small as a few microns in diameter, are usually gold-plated polymers or nickel particles. The interconnection, between the anisotropic conductive adhesive or anisotropic conductive films 121, 121′ of the LCD display circuit board and the Indium-tin oxide layers 21, 21′ of the LCDs 2, 2′, is achieved by causing the break of the conductive particles with the hot bar. Hence the electricity is conducted along the films. The above process is called thermocompression process. Furthermore, during the thermocompression process the space between the Indium-tin oxide layers 21, 21′ and the anisotropic conductive films 121, 121′ are filled with the sticky polymers.

The core substance of the conductive particles is the thermosetting and the thermoplastic polymers. Further, the surface of core particles is processed by the method of surface metalization so as to make conductive particles. The requirement of the product is that the fine pitch is under 0.1 mm. The present invention can be applied to a fine pitch interconnection in the following fields: anisotropic conductive film (ACF), anisotropic conductive adhesive (ACA), liquid crystal display (LCD)/TAB, liquid crystal display (LCD)/FPC, chip of glass (COG), chip on film (COF), electrolumine scence (EL) electrode, flip chip, and etc. Thus, the present invention with a fine pitch interconnection is indispensable in the LCD and semiconductor industries.

The above-mentioned polymers of conductive particles can be plated with a layer of nickel, copper, gold, or silver so as to form 0.5-4 mm particles in diameter. Furthermore, the techniques of emulsification synthesis and surface transforming are used for metalizing the surface of the polymers. Accordingly, the cores of the conductive particles are polymers with even particles having same diameters so that they can enhance the conductivity while connected. The anisotropic conductive adhesive or anisotropic conductive films 121, 121′ has an area the same with the area of the indium-tin oxide layers 21, 21′ so that the impedance is reduced. Therefore, since the conductive particles on the anisotropic conductive film 121, 121′ have even sizes and good conductivity. The anisotropic conductive film 121, 121′ provided in the present invention can be adapted to the standards in the IC industry. In other words, even if the pitch is broadened up to 0.5 mm owing to the product requirement, the anisotropic conductive film is still smooth and has excellent conductive interconnection.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

1. A flexible printed circuit board comprising:
a substrate layer;
at least a circuit layer formed on said substrate layer; and
a conductive film layer formed on one end of said circuit layer, characterized in that a pitch of said conductive film layer is broadened to be ranged from 0.5 mm to 3.0 mm.

2. The flexible printed circuit board according to claim 1, wherein the other end of said circuit layer is formed to be a golden-finger region and is electrically connected to the LCD circuit board.

3. The flexible printed circuit board according to claim 1, wherein said conductive film comprises conductive particles and sticky polymers.

4. The flexible printed circuit board according to claim 3, wherein said conductive particles are one of metal-plated polymer particles and nickel particles.

5. The flexible printed circuit board according to claim 4, wherein said metal of said metal-plated polymer particles is selected from a group consisting of a nickel, a copper, a gold, and a silver.

6. The flexible printed circuit board according to claim 1, wherein said substrate layer is a plastic layer.

7. The flexible printed circuit board according to claim 6, wherein said plastic layer comprises a polyimide layer and a polypropylene/epoxy resin layer.

8. The flexible printed circuit board according to claim 1, wherein said plastic layer comprises a polyimide layer.

9. The flexible printed circuit board according to claim 1, wherein said circuit layer is a copper circuit layer.

10. The flexible printed circuit board according to claim 1 further comprising an integrated circuit disposed thereon which is packaged by using one of a tape carrier package and a chip on film.

11. The flexible printed circuit board according to claim 1 further comprising surface mounting devices (SMD).

12. The flexible printed circuit board according to claim 1, wherein said conductive film is an anisotropic conductive film.

13. The flexible printed circuit board according to claim 1, wherein said flexible circuit board is connected to a liquid crystal display via said conductive film layer.

14. A flexible printed circuit board comprising:
at least two substrate layer;
at least a circuit layer formed between every adjacent two said substrate layer; and
at least a conductive film layer formed on one end of said circuit layer, characterized in that a pitch of said conductive film layer is broadened to be ranged from 0.5 mm to 3.0 mm.

15. The flexible printed circuit board according to claim 14, wherein the other end of said circuit layer is formed to be a golden-finger region and is electrically connected to the LCD circuit board.

16. The flexible printed circuit board according to claim 14, wherein said conductive film comprises conductive particles and sticky polymers.

17. The flexible printed circuit board according to claim 16, wherein said conductive particles are one of metal-plated polymer particles and nickel particles.

18. The flexible printed circuit board according to claim 17, wherein said metal of said metal-plated polymer particles is selected from a group consisting of a nickel, a copper, a gold, and a silver.

19. The flexible printed circuit board according to claim 14, wherein said substrate layer is a plastic layer.

20. The flexible printed circuit board according to claim 14 further comprising surface mounting devices (SMD).
